(19) United States
(12) Patent Application Publication
(10) Pub. No.: US 2025/0147438 A1
(43) Pub. Date: May 8, 2025

(54) INSPECTION APPARATUS, MOTORIZED APERTURES, AND METHOD BACKGROUND

(71) Applicant: ASML Netherlands B.V., Veldhoven (NL)

(72) Inventors: Krishanu SHOME, Cheshire, CT (US); Emily Rose FINAN, Norwalk, CT (US); Kirill Urievich SOBOLEV, Brookfield, CT (US); Joshua ADAMS, Wilton, CT (US); Jonathan S. RODNEY, White Plains, NY (US); Yuxiang LIN, Wilton, CT (US); Eric Brian CATEY, Danbury, CT (US)

(73) Assignee: ASML Netherlands B.V., Veldhoven (NL)

(21) Appl. No.: 18/835,287

(22) PCT Filed: Jan. 4, 2023
(86) PCT No.: PCT/EP2023/050136

§ 371 Date: Aug. 1, 2024

Related U.S. Application Data
(60) Provisional application No. 63/307,439, filed on Feb. 7, 2022.

(51) Int. Cl. G03F 7/00; G02B 5/00; G02B 26/00

(52) U.S. Cl. CPC G03F 7/706849; G02B 5/005; G02B 26/007; G03F 7/70191; G03F 7/70308; G03F 7/70525; G03F 7/70575; G03F 7/706851; G03F 7/70825; G03F 7/7085; G03F 7/70958

(57) ABSTRACT

A system includes an imaging system, a spatial filter, and a detector. The system is configured to receive a plurality of diffraction orders. The spatial filter is configured to block one or more undesired diffraction orders of the plurality of diffraction orders and to pass one or more desired diffraction orders of the plurality of diffraction orders. The spatial filter includes one or more obscurations having an angular dependent radius that varies azimuthally. The detector is configured to receive and measure an intensity of the one or more desired diffraction orders. The spatial filter is motorized.

### CROSS-REFERENCE TO RELATED APPLICATIONS

This application claims priority of U.S. application 63/307,439 which was filed on Feb. 7, 2022 and which is incorporated herein in its entirety by reference.

### FIELD

The present disclosure relates to filtering diffraction orders, for example, motorized apertures for blocking high order diffraction beams in inspection and lithographic tools.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned. Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps may require different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus may use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters may include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

### SUMMARY

Accordingly, it is desirable to improve measurement of target mark asymmetry in metrology apparatuses for improving capture speed at a plurality of wavelengths.

In some embodiments, a system includes an imaging system, a spatial filter, and a detector. The system is configured to receive a plurality of diffraction orders. The spatial filter is configured to block one or more undesired diffraction orders of the plurality of diffraction orders and to pass one or more desired diffraction orders of the plurality of diffraction orders. The spatial filter includes one or more obscurations having an angular dependent radius that varies azimuthally. The detector is configured to receive and measure an intensity of the one or more desired diffraction orders.

In some embodiments, a spatial filter includes an aperture. The aperture includes one or more obscurations having an angular dependent radius that azimuthally varies from a first radial distance to a second radial distance, and one or more ridges located at an inner edge of the one or more obscurations. The aperture is configured to rotate about its center.

In some embodiments, a method includes receiving a plurality of diffraction orders, blocking, using a spatial filter, one or more undesired diffraction orders of the plurality of diffraction orders and passing one or more desired diffraction orders of the plurality of diffraction orders, and measuring an intensity of the one or more desired diffraction orders. The spatial filter includes one or more obscurations having an angular dependent radius that varies azimuthally.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of inspection apparatuses, according to some embodiments.

FIGS. 5A, 5B, and 5C show schematic of pupil planes for different target types, according to some embodiments.

FIG. 6A shows a schematic of a spatial filter, according to some embodiments.

FIG. 6B shows a schematic of a blocker, according to some embodiments.

FIGS. 7A and 7B show schematics of optical systems, according to some embodiments.

FIG. 8A is a schematic of a pupil plane, according to some embodiments.

FIGS. 8B-8H show schematics of hybrid spatial filters, according to some embodiments.

FIG. 9 shows a schematic of an optical system, according to some embodiments.

FIG. 10 shows a schematic of diffraction orders in a pupil plane, according to some embodiments.

FIGS. 11A and 11B show schematics of hybrid spatial filters, according to some embodiments.

FIG. 12 show a schematic of an axicon optical system, according to some embodiments.

FIG. 13 shows a schematic of an optical system, according to some embodiments.

FIG. 14 shows a flowchart of a method, according to some embodiments

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

### Example Lithographic Systems

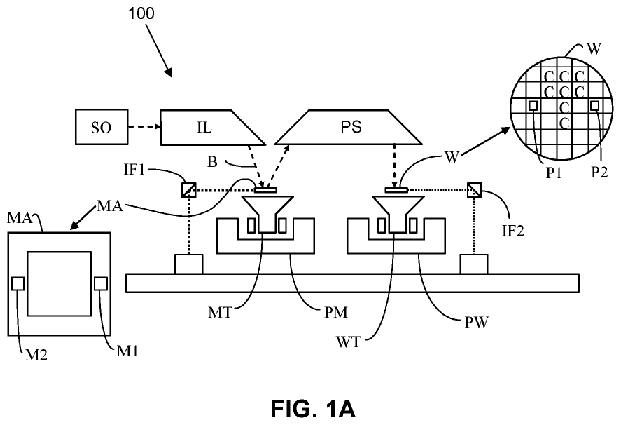

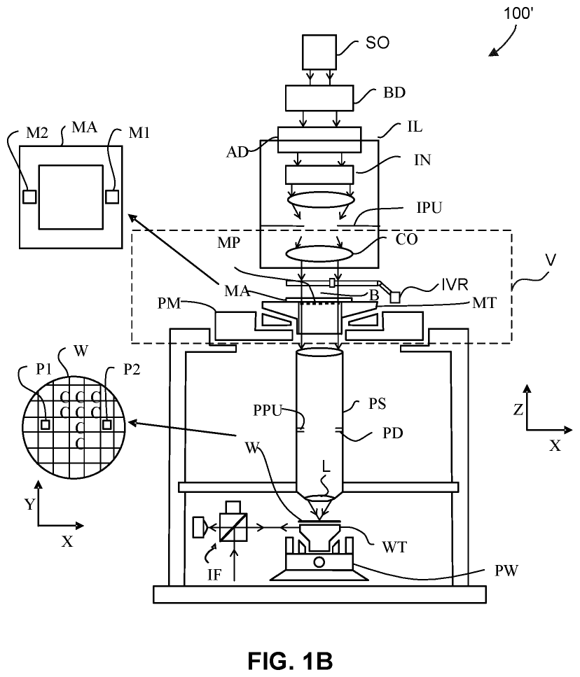

FIGS. 1A and 1B show schematic illustrations of a lithographic apparatus 100 and lithographic apparatus 100′, respectively, in which embodiments of the present disclosure may be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL may include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT may use mechanical, vacuum, electrostatic, or other clamping techniques to hold the patterning device MA. The support structure MT may be a frame or a table, for example, which may be fixed or movable, as required. By using sensors, the support structure MT may ensure that the patterning device MA is at a desired position, for example, with respect to the projection system PS.

The term “patterning device” MA should be broadly interpreted as referring to any device that may be used to impart a radiation beam B with a pattern in its cross-section, such as to create a pattern in the target portion C of the substrate W. The pattern imparted to the radiation beam B May correspond to a particular functional layer in a device being created in the target portion C to form an integrated circuit.

The terms “inspection apparatus,” “metrology system,” or the like may be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA may be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which may be individually tilted so as to reflect an incoming radiation beam in different directions. The tilted mirrors impart a pattern in the radiation beam B, which is reflected by a matrix of small mirrors.

The term “projection system” PS may encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment may be used for EUV or electron beam radiation since other gases may absorb too much radiation or electrons. A vacuum environment may therefore be provided to the whole beam path with the aid of a vacuum wall and vacuum pumps.

Lithographic apparatus 100 and/or lithographic apparatus 100′ may be of a type having two (dual stage) or more substrate tables WT (and/or two or more mask tables). In such “multiple stage” machines, the additional substrate tables WT may be used in parallel, or preparatory steps may be carried out on one or more tables while one or more other substrate tables WT are being used for exposure. In some situations, the additional table may not be a substrate table WT.

The lithographic apparatus may also be of a type wherein at least a portion of the substrate may be covered by a liquid having a relatively high refractive index, e.g., water, so as to fill a space between the projection system and the substrate. An immersion liquid may also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

Referring to FIGS. 1A and 1B, the illuminator IL receives a radiation beam from a radiation source SO. The source SO and the lithographic apparatus 100, 100′ may be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO may be an integral part of the lithographic apparatus 100, 100′, for example, when the source SO is a mercury lamp. The source SO and the illuminator IL, together with the beam delivery system BD, if required, may be referred to as a radiation system.

The illuminator IL may include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator may be adjusted. In addition, the illuminator IL may comprise various other components (in FIG. 1B), such as an integrator IN and a condenser CO. The illuminator IL may be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT may be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W may be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP may include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line may be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration may be reduced by providing radiation poles (not shown) in opposite quadrants of the illumination system pupil IPU. Further, in some embodiments, astigmatism aberration may be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT may be moved accurately (for example, so as to position different target portions C in the path of the radiation beam B). Similarly, the first positioner PM and another position sensor (not shown in FIG. 1B) may be used to accurately position the mask MA with respect to the path of the radiation beam B (for example, after mechanical retrieval from a mask library or during a scan).

In general, movement of the mask table MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the mask table MT may be connected to a short-stroke actuator only or may be fixed. Mask MA and substrate W may be aligned using mask alignment marks M1, M2, and substrate alignment marks P1, P2. Although the substrate alignment marks (as illustrated) occupy dedicated target portions, they may be located in spaces between target portions (known as scribe-lane alignment marks). Similarly, in situations in which more than one die is provided on the mask MA, the mask alignment marks may be located between the dies.

Mask table MT and patterning device MA may be in a vacuum chamber V, where an in-vacuum robot IVR may be used to move patterning devices such as a mask in and out of vacuum chamber. Alternatively, when mask table MT and patterning device MA are outside of the vacuum chamber, an out-of-vacuum robot may be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ may be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C may be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT may be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO may be employed and the programmable patterning device is updated as required after each movement of the substrate table WT or in between successive radiation pulses during a scan. This mode of operation may be readily applied to maskless lithography that utilizes a programmable patterning device, such as a programmable mirror array.

Combinations and/or variations on the described modes of use or entirely different modes of use may also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

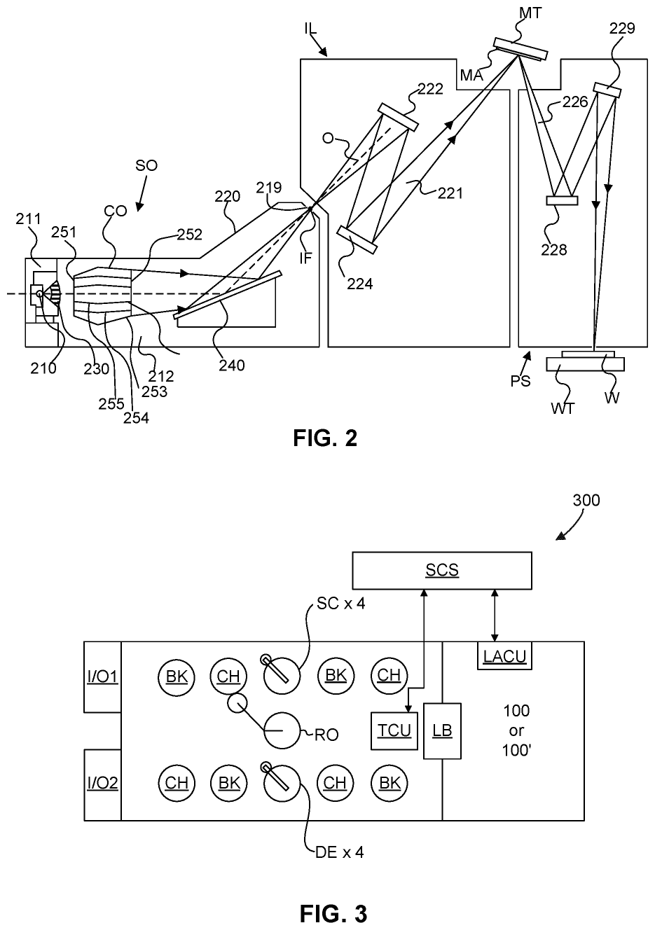

FIG. 2 shows the lithographic apparatus 100 in more detail, including the source collector apparatus SO, the illumination system IL, and the projection system PS. The source collector apparatus SO is constructed and arranged such that a vacuum environment may be maintained in an enclosing structure 220 of the source collector apparatus SO. An EUV radiation emitting plasma 210 can be formed by a discharge produced plasma source. EUV radiation may be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor may be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which may be a so-called grazing incidence collector. Radiation collector CO has an upstream radiation collector side 251 and a downstream radiation collector side 252. Radiation that traverses collector CO may be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which may include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown may generally be present in illumination optics unit IL and projection system PS. The grating spectral filter 240 can optionally be present, depending upon the type of lithographic apparatus. Further, there may be more mirrors present than those shown in the FIG. 2, for example there may be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Exemplary Lithographic Cell

FIG. 3 shows a lithographic cell 300, also sometimes referred to a lithocell or cluster, according to some embodiments. Lithographic apparatus 100 or 100′ may form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses may be operated to maximize throughput and processing efficiency.

### Exemplary Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement may be performed using the techniques described in U.S. Publication No. 2009/195768 A (Bijnen et al.), however. The full contents of both of these disclosures are incorporated herein by reference.

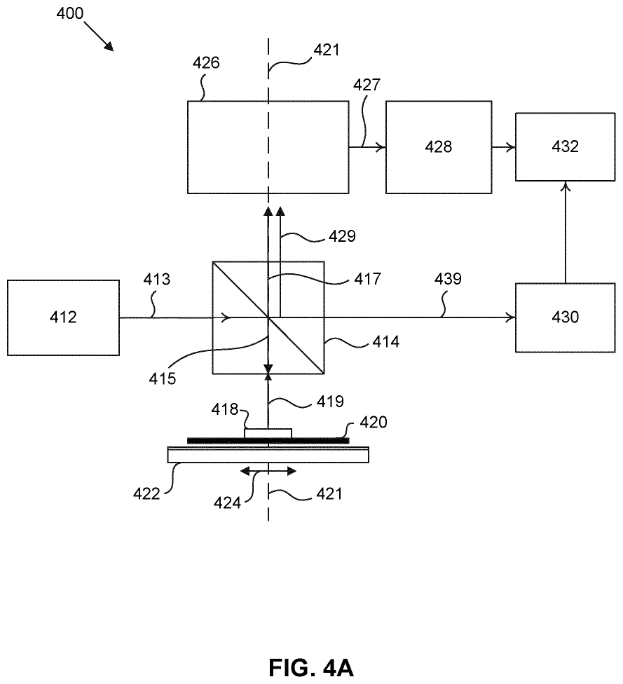

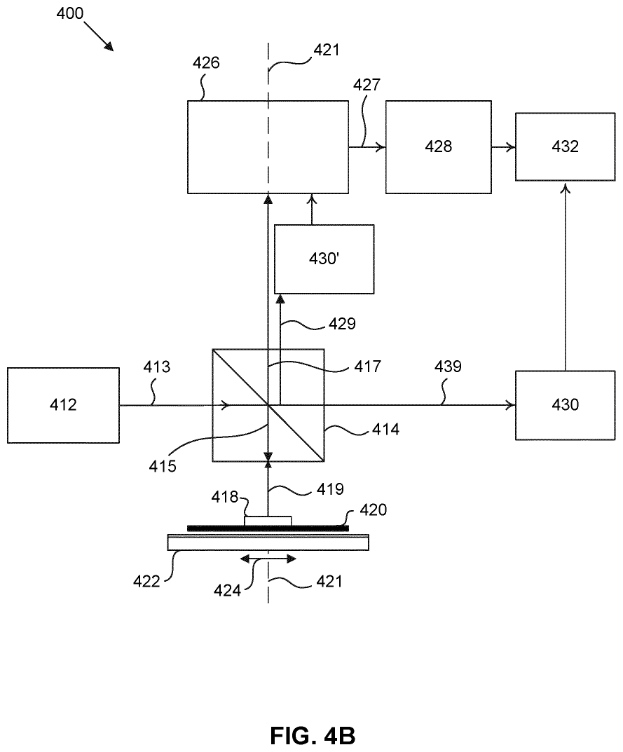

FIG. 4A shows a schematic of a cross-sectional view of an inspection apparatus 400 that may be implemented as a part of lithographic apparatus 100 or 100′, according to some embodiments. In some embodiments, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate may ensure accurate exposure of one or more patterns on the substrate.

In some embodiments, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands may be within a spectrum of wavelengths between about 500 nm to about 900 nm. In another example, the one or more passbands may be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values may improve long-term stability and accuracy of alignment systems (e.g., inspection apparatus 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some embodiments, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars may alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, may be input to the reconstruction process, performed by processing unit PU, from knowledge of the printing step and/or other scatterometry processes.

In some embodiments, beam splitter 414 can be further configured to receive diffraction radiation beam 419 and split diffraction radiation beam 419 into at least two radiation sub-beams, according to an embodiment. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements may be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that may be reflected from alignment mark or target 418. In an example of this embodiment, interferometer 426 comprises any appropriate set of optical-elements, for example, a combination of prisms that may be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference may be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data may, for example, be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some embodiments, beam analyzer 430 can be configured to receive and determine an optical state of diffracted radiation sub-beam 439. The optical state may be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some embodiments, beam analyzer 430 can be directly integrated into inspection apparatus 400, or connected via fiber optics of several types: polarization preserving single mode, multimode, or imaging, according to other embodiments.

In some embodiments, beam analyzer 430 can be further configured to determine the overlay data between two patterns on substrate 420. One of these patterns may be a reference pattern on a reference layer. The other pattern may be an exposed pattern on an exposed layer. The reference layer may be an etched layer already present on substrate 420. The reference layer may be generated by a reference pattern exposed on the substrate by lithographic apparatus 100 and/or 100′. The exposed layer may be a resist layer exposed adjacent to the reference layer. The exposed layer may be generated by an exposure pattern exposed on substrate 420 by lithographic apparatus 100 or 100′. The exposed pattern on substrate 420 can correspond to a movement of substrate 420 by stage 422. In some embodiments, the measured overlay data may also indicate an offset between the reference pattern and the exposure pattern. The measured overlay data may be used as calibration data to calibrate the exposure pattern exposed by lithographic apparatus 100 or 100′, such that after the calibration, the offset between the exposed layer and the reference layer may be minimized.

In some embodiments, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile may also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) may be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but require individual pre-amps. The number of elements is therefore limited. CCD linear arrays offer many elements that may be read-out at high speed and are especially of interest if phase-stepping detection is used.

In some embodiments, a second beam analyzer 430′ can be configured to receive and determine an optical state of diffracted radiation sub-beam 429, as shown in FIG. 4B. The optical state may be a measure of beam wavelength, polarization, or beam profile. Second beam analyzer 430′ can be identical to beam analyzer 430. Alternatively, second beam analyzer 430′ can be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some embodiments, second beam analyzer 430′ can be directly integrated into inspection apparatus 400, or it may be connected via fiber optics of several types: polarization preserving single mode, multimode, or imaging, according to other embodiments. Alternatively, second beam analyzer 430′ and beam analyzer 430 can be combined to form a single analyzer (not shown) configured to receive and determine the optical states of both diffracted radiation sub-beams 429 and 439.

In some embodiments, processor 432 receives information from detector 428 and beam analyzer 430. For example, processor 432 can be an overlay calculation processor. The information may comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some embodiments, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm may be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error may be deduced. Table 1 illustrates how this may be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value may be taken to be the reference point and, relative to this, the offset may be calculated between measured overlay and that expected due to the programmed overlay. This offset determines the overlay error for each mark or the sets of marks with similar offsets. Therefore, in the Table 1 example, the smallest measured overlay was-1 nm, at the target position with programmed overlay of 30 nm. The difference between the expected and measured overlay at the other targets is compared to this reference. A table such as Table I may also be obtained from marks and target 418 under different illumination settings. The illumination setting, which results in the smallest overlay error, and its corresponding calibration factor, can be determined and selected from the table. The selected illumination setting may be used. Following this, processor 432 can group marks into sets of similar overlay error. The criteria for grouping marks can be adjusted based on different process controls, for example, different error tolerances for different processes.

In some embodiments, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

### Exemplary Motorized Apertures for Multiwavelength Signals

Alignment is increasingly becoming a dominant contribution to overlay. There is a limit to increasing the quality of the optics and hardware without increasing costs. There are also physics limitations of increasing the effectiveness of algorithms. Mark asymmetry is inherently present on wafers. During previous generations of mark design, mark asymmetry was ignored since it is a contribution coming from the marks and not the sensor.

Intensity signals captured using intensity channels can decouple mark asymmetry and real wafer deformation. Without using the intensity channels, which are defined in detail below, mark asymmetry can be determined by evaluating and training alignment recipes (e.g., choosing different wavelengths and colors from the phase measurements) from overlay data.

Different diffraction orders can be measured in phase channels. Signals associated with each diffraction order may vary at different frequencies during a scan. Thus, signals of different diffraction orders may be detected simultaneously in a detector. Diffraction order may experience a different and uncorrelated (dependent on the stack, asymmetry mode, and mark design) error because of mark asymmetry. However, for intensity channels, each diffraction order is measured independently. In some embodiments, the +/−1 diffraction order is the desired diffraction order (e.g., for 1.6-3.5 μm marks). All other orders (e.g., higher orders) are undesired orders and can be blocked for the intensity channels.

According to some embodiments, interferometer 426 and detector 428 can include (or be part of) one or more phase channels of metrology system 400 of FIGS. 4A and 4B that can be configured to determine alignment and/or a position of alignment mark or target 418. In some embodiments, beam analyzer 430 and/or beam analyzer 430′ can include (or be part of) one or more intensity channels of metrology system 400 of FIGS. 4A and 4B.

As discussed in more details below, the intensity channels of metrology system 400 of FIGS. 4A and 4B can be designed such that different diffraction orders diffracted from alignment mark or target 418 are separated at, for example, beam analyzer 430 and/or beam analyzer 430′. In other words, instead of (or in addition to) measuring a total intensity (e.g., I₊ₜₒₜₐₗ=I₊₁+I₊₂+I₊₃+ . . . ), the intensity channel can measure the intensity of different diffraction orders separately (e.g., I₊₁ and I₋₁, I₊₂ and I₋₂, etc.) Here, I is the measured intensity. According to some embodiments, by blocking undesired diffraction orders and separately detecting desired diffraction orders, metrology system 400 can be configured to measure and determine, for example, intensity imbalance (e.g., difference in intensities) for different diffraction orders. In some aspects, an output of the intensity channels is the parameter Q. Parameter Q may correspond to a measure of a difference between the power of the + and − diffraction orders for each wavelength of a plurality of wavelengths.

According to some embodiments, the intensity imbalance of the diffraction orders can be due to asymmetry in alignment mark or target 418. Additionally, or alternatively, the background of alignment mark or target 418 can also contribute to the intensity imbalance of the diffraction orders.

In some embodiments, as discussed in more details below, by determining and measuring the intensity imbalance of the diffraction orders, metrology system 400 can determine a correction factor that can be used to correct the characteristic of alignment mark or target 418 (e.g., alignment, position, overlay error, etc.) that is determined by metrology system 400.

In some embodiments, higher orders may contaminate the algorithm and give errors to mark asymmetry correction (e.g., correction factor). For different mark pitches, the higher diffraction order (order number m>1) spots are located at different locations in the pupil plane. Thus, desired diffraction orders may move towards or away from the center of pupil as a function of a grating pitch and wavelength.

In some embodiments, a single aperture mask may block higher orders from passing through the optical system for all pitch ranges supported by inspection apparatus 400. For example, the same region of the pupil allows first order diffraction spots for 1.6 μm pitch alignment marks, but block higher orders for 3.2 μm pitch marks.

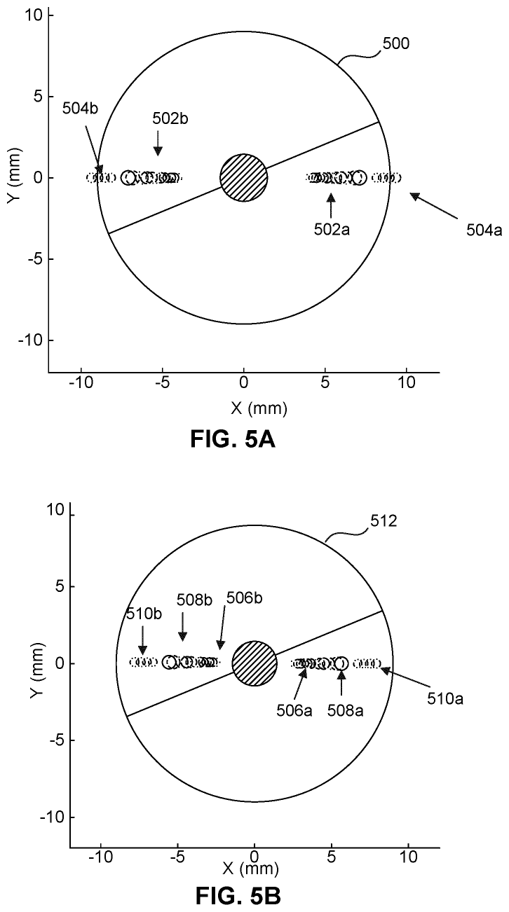

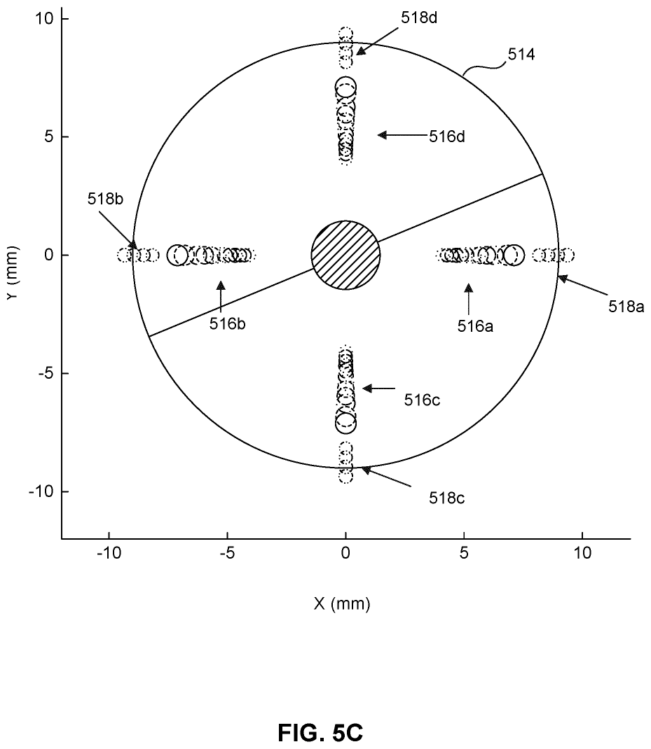

FIG. 5A is a schematic of a pupil plane (i.e., pupil image) 500 for a first alignment mark, according to some embodiments. Pupil plane 500 includes positive first diffraction order 502a and negative first diffraction order 502b. Pupil plane 500 can also include positive second diffraction order 504a and negative second diffraction order 504b. First alignment mark may have a pitch of 1.6 μm, for example. In some aspects, a pitch of the alignment mark may be from 1.6 μm to 3.5 μm. The orders are located at different radial positions in pupil plane 500. In addition, each order may include a plurality of wavelengths. The plurality of wavelengths are shown with different line types in pupil plane 500.

FIG. 5B is a schematic of a pupil plane 512 for a second alignment mark, according to some embodiments. Pupil plane 512 can include positive first diffraction order (+1) 506a, negative first diffraction order (−1) 506b, positive second diffraction order (+2) 508a, negative second diffraction order (−2) 508b, positive third diffraction order (+3) 510a, and negative third diffraction order (−3) 510b. Second alignment mark can have a pitch of 3.2 μm. As shown in FIG. 5B, second and third diffraction orders pass through pupil plane 512 in the same region where the first order passes for the first alignment mark.

FIG. 5C is a schematic of a pupil plane 514 for a third alignment mark, according to some embodiments. Pupil plane 514 shows both diffraction orders in two lateral directions (e.g., in x-direction and y-direction). For example, diffraction orders located along the x-direction can be present simultaneously with diffraction orders located along the y-direction. Pupil plane 514 can include positive first diffraction order 516a, negative first diffraction order 516b, positive high diffraction order 518a, and negative high diffraction order 518b in x-direction. Pupil plane 514 can also include first diffraction order 516d, negative first diffraction order 516c, positive high diffraction order 518d, and negative high order diffraction 518c in y-direction.

In some embodiments, during scanning of the third alignment mark, diffraction orders along the x-direction and diffraction orders along y-direction are blocked separately. For example, diffraction spots located along the x-direction and diffraction spots located along the y-direction are blocked sequentially. In some embodiments, third alignment mark may be a combined bidirectional (CB) mark or a two dimensional mark.

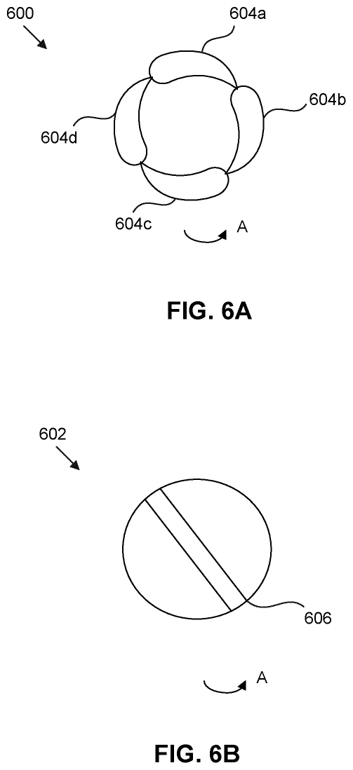

FIG. 6A shows a schematic of a spatial filter 600, according to some embodiments. Spatial filter 600 can be configured to block one or more undesired diffraction orders (e.g., high orders). Spatial filter 600 can include one or more obscurations. For example, spatial filter 600 (having a central aperture) can comprise obscurations 604a, 604b, 604c, and 604d. In some aspects, obscurations 604a, 604b, 604c, and 604d can have an angular dependent radius that varies azimuthally. A respective radius of each obscurations 604a, 604b, 604c, and 604d may vary from a first radial distance to a second radial distance. In some aspects, obscurations 604a, 604b, 604c, and 604d may have the same shape. The depicted shape of each obscuration 604a, 604b, 604c, and 604d is illustrated by way of example, not limitation.

In some embodiments, spatial filter 600 can be a motorized spatial filter. Spatial filter 600 can rotate around its center in a direction A, for example. Thus, the radius of openings can be varied by rotating spatial filter 600.

Spatial filter 600 can be used to block undesired diffraction orders from a plurality of marks having diffraction spots in the x-direction, y-direction, and/or ±45°.

FIG. 6B shows a schematic of a blocker 602, according to some embodiments. Blocker 602 can include an obscuration 606. Obscuration 606 can have a rectangular shape that may block positive and negative diffraction orders along a first direction. Blocker 602 can be a motorized blocker configured to rotate around its center in the direction A. Thus, positive and negative diffraction orders along a first direction may be blocked by rotating blocker 602. For example, if the positive and negative diffraction orders along the y-direction are undesired, blocker 602 can be rotated such that obscuration 606 is in the y-direction. Then, blocker 602 can sequentially rotated such that obscuration 606 is in the x-direction, in order to collect measurement associated with the desired diffraction orders in the y-direction.

Spatial filter 600 and blocker 602 can be controlled individually by a motor coupled to a processor or controller.

### Exemplary Apparatuses for Target Asymmetry Measurement

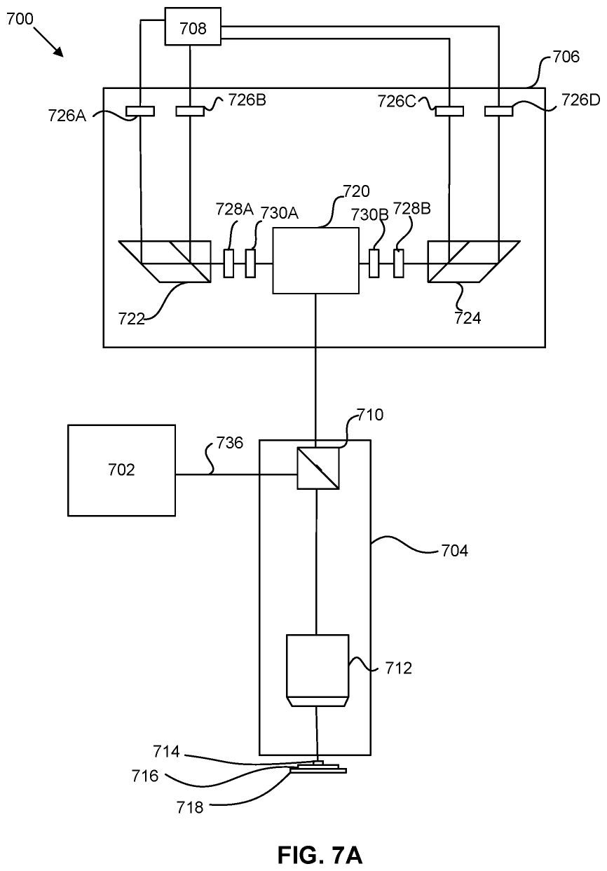

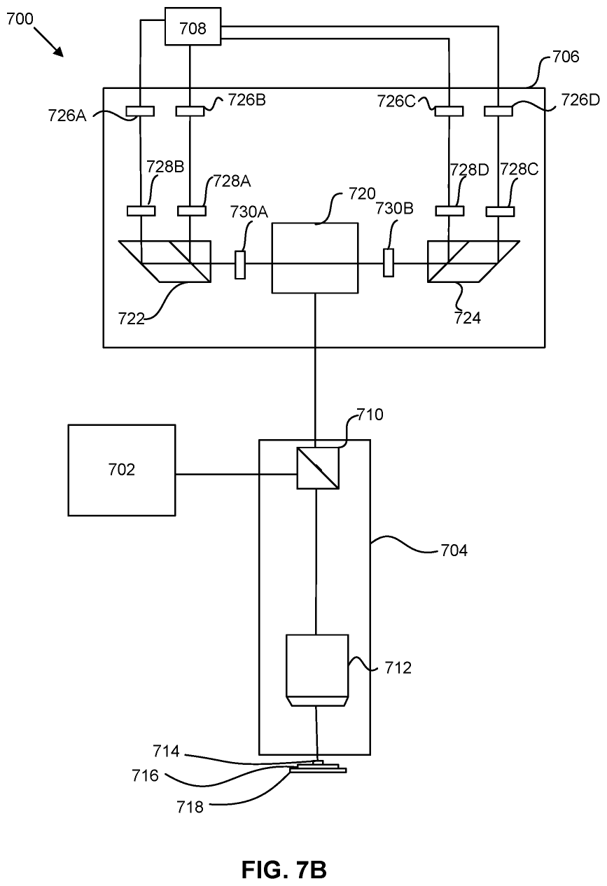

FIG. 7A shows a schematic of an optical system 700, according to some embodiments. In some embodiments, system 700 can also represent a more detailed view of inspection apparatus 400 (FIGS. 4A and 4B). In some embodiments, system 700 includes an illumination system 702, an optical system 704, a detection system 706, and a processor 708. Optical system 704 can comprise a reflective element 710 (e.g., spot mirror) and an optical element 712 (e.g., an objective lens). The reflective element 710 can act as a field stop for zero order diffracted radiation. It should be appreciated the structures drawn within illumination system 702 and optical system 704 are not limited to their depicted positions. The positions of structures can vary as necessary, for example, as designed for a modular assembly.

FIG. 7A shows a non-limiting depiction of system 700 inspecting a target 714 (also “target structure”) on a substrate 716. The substrate 716 is disposed on a stage 718 that is adjustable (e.g., a support structure that can move).

In some embodiments, target 714 can comprise a diffractive structure. Target 714 can reflect, refract, diffract, scatter, or the like, incident radiation. Target 714 can be an alignment mark or target 418 of FIGS. 4A and 4B. For ease of discussion, and without limitation, radiation that interacts with a target will be termed scattered radiation throughout. The scattered radiation can be collected by optical element 712.

Illumination system 702 can be configured to generate a radiation beam 736 to irradiate target 714. Optical system 704 can be configured to collect diffraction orders diffracted from target 714 and to guide the diffraction orders to detection system 706.

In some embodiments, detection system 706 can include a beam splitter 720 (one or more beam splitters) and one or more detectors. The scattered radiation can be passed by optical element 712 and to beam splitter 720. Beam splitter 720 can split a portion of an optical signal into two paths. In some embodiments, each path may correspond to a polarization channel. In some aspects, a portion of the optical path is passed through beam splitter 720 to phase channels of system 700 (not shown).

In one aspect, an optical element 722 (e.g., split mirror) can split the optical signal into two paths A and B. One path can contain one or more positive orders (e.g., +1, +2), and the other path can contain one or more negative orders (e.g., −1, −2). Similarly, an optical element 724 can split the optical signal into two paths C and D. The radiation of each path A, B, C, and D can be collected by a respective lens assembly (not shown) that can focus the radiation field into each detector 726A, 726B, 726C, and 726D respectively. Detectors 726A, 726B, 726C, and 726D can be used as (or be part of) beam analyzers 430 and/or 430′ of FIGS. 4A and 4B. Each detector can provide time-varying signals (e.g., waveformis) synchronized with the physical scanning movement between system 700 and target 714. Signals from the detectors can be processed by processor 708.

In some embodiments, detection system 706 can further include a first spatial filter 730A, a second spatial filter 730B, a first blocker 728A, and a second blocker 728B. Each of first spatial filter 730A, second spatial filter 730B, first blocker 728A, and second blocker 728B can be coupled to a respective motor that is controlled individually. In some aspects, first spatial filter 730A and second spatial filter 730B can be controlled to block undesired diffraction orders (e.g., diffraction orders higher than +1 orders).

In some embodiments, first blocker 728A and second blocker 728B can be controlled to block diffraction orders in the x-direction and or y-direction. In some aspects, first blocker 728A and first spatial filter 730A can be positioned in the optical path between beam splitter 720 and optical element 722. In some aspects, second blocker 728B and second spatial filter 730B can be positioned in the optical path between beam splitter 720 and optical element 724.

In some embodiments, first blocker 728A and second blocker 728B can be similar to blocker 602 of FIG. 6B. In some embodiments, first spatial filter 730A and spatial filter 730B can be similar to spatial filter 600 of FIG. 6A.

In some embodiments, target 714 can be a one-dimensional target. For example, target 714 can include a grating with segments (e.g., but not limited to grating lines) in x-direction or a grating with segments in y-direction. In some embodiments, target 714 can include segments that are diagonal or are under any other angle. Target 714 can include dual pitch marks. Target 714 can include segments in, for example, x and y directions with different pitches.

While the examples described herein concentrate on the ±1^{st} order diffraction signals as desired diffraction orders, it will be understood that the disclosure extends to the capture and analysis of higher orders (e.g., ±2^{nd} order, ±3^{rd} order, etc.).

In some embodiments, diffraction orders in a first direction and in a second direction may be blocked separately for positive and negative orders, as shown in FIG. 7B. First blocker 728A can be positioned in a positive order path after optical element 722. Second blocker 728B may be positioned in a negative order path after optical element 722. In some embodiments, a third blocker 728C and a fourth blocker 728D can be positioned respectively in the positive and negative order paths after optical element 724. Each of first blocker 728A, second blocker 728B, third blocker 728C, and fourth blocker 728D can be coupled to a respective motor (not shown). The motors may be configured to control first blocker 728A, second blocker 728B, third blocker 728C, and fourth blocker 728D. For example, the motor may be configured to rotate first blocker 728A to block positive first diffraction order in the x-dimension during a first measurement and to block positive first diffraction order in the y-direction in a second measurement.

First blocker 728A, second blocker 728B, third blocker 728C, and fourth blocker 728D can be similar to blocker 602 of FIG. 6B. In some aspects, having four blockers as shown in FIG. 7B as opposed to two blockers has the advantage to minimize space requirement between beam splitter 720 and each of optical element 722 and optical element 724, respectively.

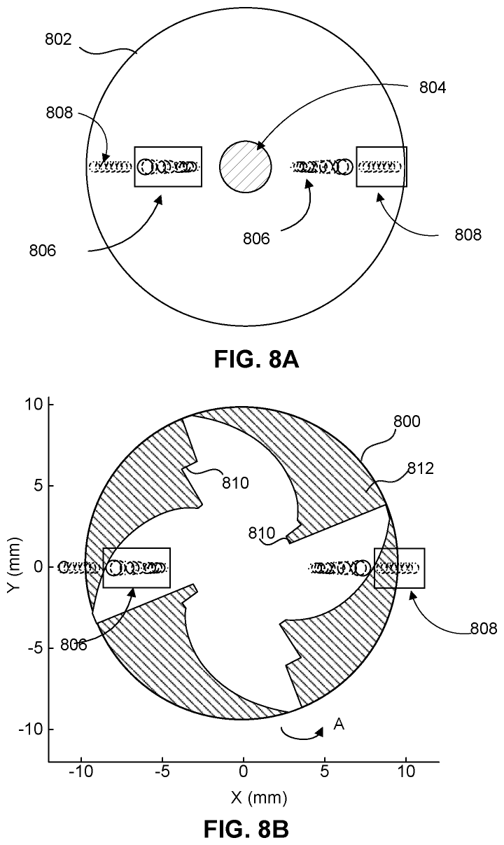

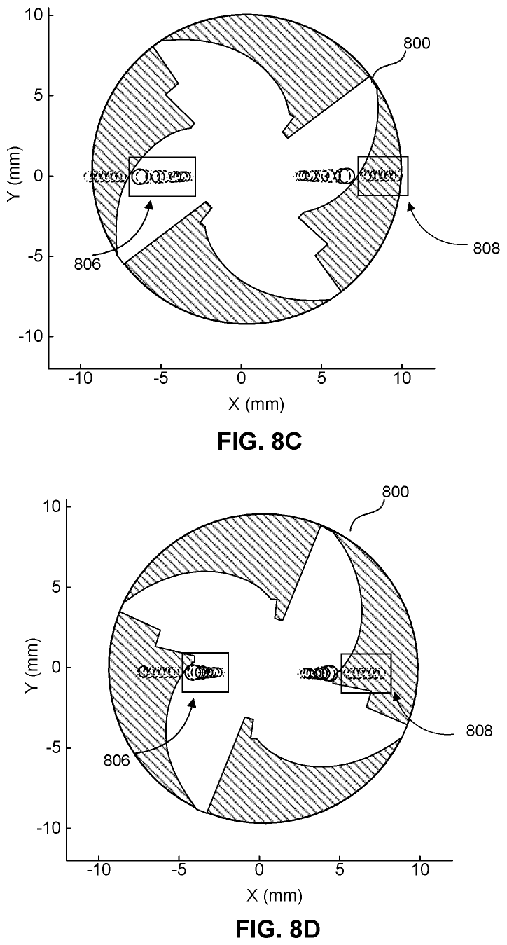

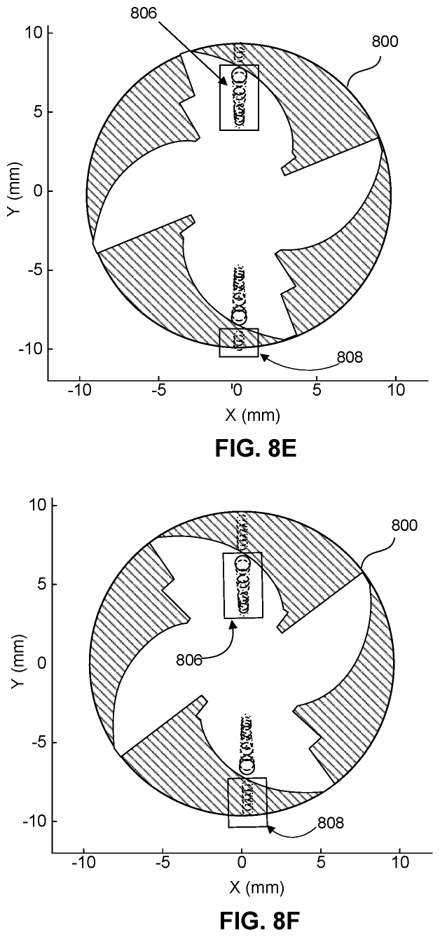

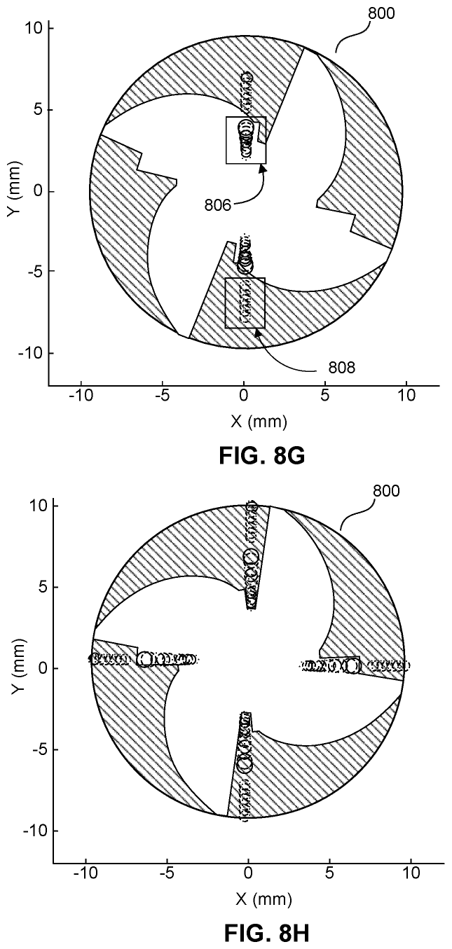

FIG. 8A is a schematic of a pupil plane 802, according to some embodiments. Pupil plane 802 can include a spot mirror shadow 804 and first diffraction orders 806 at a plurality of wavelengths and higher orders 808 at the plurality of wavelengths. First diffraction orders 806 can include positive and negative first diffraction orders.

FIG. 8B is a schematic of a hybrid spatial filter 800. In some embodiments, hybrid spatial filter 800 can be rotated between the different positions based on a target type (e.g., CB mark). The hybrid spatial filter 800 can rotate around its center in direction A. Thus, hybrid spatial filter 800 is rotated such as the desired diffraction orders are passed and the undesired diffraction orders are blocked despite a change in the position of the desired diffraction orders due to the target type (e.g., different pitch).

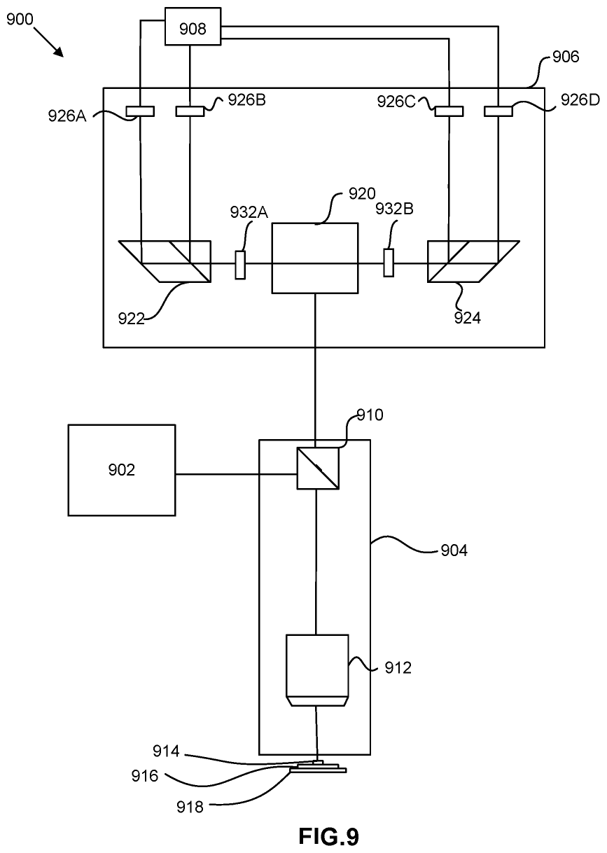

Hybrid spatial filter 800 (e.g., aperture mask) is configured to block undesired diffraction orders (e.g., high diffraction orders) and diffraction orders along an undesired direction (e.g., x-direction, y-direction) using a single motor. Thus, hybrid spatial filter 800 can be used as an alternative to separate spatial filter 600 and blocker 602 of FIG. 6. Thus, one hybrid spatial filter may be used in each polarization path as further discussed below in relation with FIG. 9.

In some embodiments, hybrid spatial filter 800 can comprise a rotatable aperture that includes one or more obscurations 812 having an angular dependent radius. The radius of an obscuration in each section varies from a first radial distance to as second radial distance. In some embodiments, hybrid spatial filter 800 can include one or more ridges (or discontinuities) 810 located at an inner edge of the one or more obscurations. In some embodiments, ridges 810 can pass all diffraction orders in a first dimension and block all diffraction orders in a second dimension.

The embodiments of this disclosure are not limited to this exemplary design and the hybrid spatial filter 800 can include other designs (e.g., different number of opaque obscurations/openings, different shapes for obscurations/openings, and the like).

FIGS. 8C-8H show schematics of hybrid spatial filter 800 at different positions, according to some embodiments. As can be seen in FIG. 8B, only first diffraction orders 806 (positive and negative diffraction order) along the x-direction are passed. Other diffraction orders fall outside of the opening and are blocked by obscurations 812. For example, diffraction orders 808 are blocked.

Hybrid spatial filter 800 can be rotated as illustrated in FIGS. 8C-8H when the position of the desired diffraction order changes (e.g., first diffraction order 806). Diffraction orders shown in FIG. 8B correspond to an alignment mark having a pitch of 1.6 μm in the x-direction. FIG. 8C shows diffraction orders for an alignment mark having a pitch of 2 μm in the x-direction. The location of first diffraction order 806 and higher orders 808 has shifted toward a center of hybrid spatial filter. Thus, hybrid spatial filter 800 is rotated such as the radius of the opening is reduced such as to block high orders 808. For an alignment mark having a pitch of 3.2 μm in the x-direction, the locations of first diffraction order 802 and high orders 808 are further shifted towards the center of the pupil plane as shown in FIG. 8D. Thus, the hybrid spatial filter can be further rotated to narrow the opening in order to block high orders 808.

Diffraction orders shown in FIG. 8E correspond to an alignment mark having a pitch of 1.6 μm in the y-direction. FIG. 8F shows diffraction orders for an alignment mark having a pitch of 2 μm in the y-direction. The location of first diffraction order 806 and higher orders 808 has shifted toward a center of hybrid spatial filter. Thus, hybrid spatial filter 800 is rotated such as the radius of the opening is reduced such as to block high orders 808. For an alignment mark having a pitch of 3.2 μm in the x-direction, the locations of first diffraction order 802 and high orders 808 are further shifted towards the center of the pupil plane as shown in FIG. 8G. Thus, the hybrid spatial filter 800 can be further rotated to narrow the opening in order to block high orders 808.

Diffraction orders shown in FIG. 8H correspond to a two-dimensional alignment mark having a pitch of 2 μm in the y-direction and in the x-direction. Diffraction orders appears in the x-direction and in the y-direction. Hybrid spatial filter 800 is rotated such as one or more ridges (or discontinuities) 810 can block the diffraction orders along the y-dimension. In addition, high orders 808 along the x-direction are blocked. The pitches depicted in these figures are given by way of example, not limitation.

FIG. 9 shows a schematic of an optical system 900, according to some embodiments. In some embodiments, system 900 can also represent a more detailed view of inspection apparatus 400 (FIGS. 4A and 4B). In some embodiments, system 900 includes an illumination system 902, an optical system 904, a detection system 906, and a processor 908. Optical system 904 can comprise a reflective element 910 (e.g., spot mirror) and an optical element 912 (e.g., an objective lens). Reflective element 910 can act as a field stop for zero order diffracted radiation. It should be appreciated the structures drawn within illumination system 902 and optical system 904 are not limited to their depicted positions. The positions of structures can vary as necessary, for example, as designed for a modular assembly.

FIG. 9 shows a non-limiting depiction of system 900 inspecting a target 914 (also “target structure”) on a substrate 916. Substrate 916 is disposed on a stage 918 that is adjustable (e.g., a support structure that can move).

In some embodiments, target 914 can comprise a diffractive structure. Target 914 can reflect, refract, diffract, scatter, or the like, radiation. For ease of discussion, and without limitation, radiation that interacts with a target will be termed scattered radiation throughout. The scattered radiation can be collected by optical element 912.

The detection system 906 can include a beam splitter 920 (one or more beam splitters) and one or more detectors. The scattered radiation can be passed by optical element 912 and to beam splitter 920. Beam splitter 920 can split a portion of optical signal into two paths. In some embodiments, each path may correspond to a polarization channel.

In some embodiments, an optical element 922 (e.g., split mirror) can split the optical signal into two paths A and B. One path can contain one or more positive orders (e.g., +1, +2), and the other can contain one or more negative orders (e.g., −1, −2). Similarly, an optical element 924 can split the optical signal into two paths C and D. The radiation of each path A, B, C, and D can be collected by a respective lens assembly (not shown) that can focus the radiation field into each detector 926A, 926B, 926C, and 926D respectively. Each detector can provide time-varying signals (e.g., waveforms) synchronized with the physical scanning movement between system 900 and target structure 914. Signals from the detectors can be processed by processor 908. Detection system 906 can further include one or more phase channels (not shown).

In some embodiments, detection system 906 can further include a first hybrid spatial filter 932A and a second hybrid spatial filter 932B. Each of first hybrid spatial filter 932A and second hybrid spatial filter 932B can be coupled to a respective motor that is controlled individually. In some aspects, first hybrid spatial filter 932A and second hybrid spatial filter 932B can be controlled to block undesired diffraction orders in one lateral directions. For example, first hybrid spatial filter 932A and second hybrid spatial filter 932B can block all diffraction orders in one direction and one or more undesired diffraction orders (e.g., diffraction orders higher than one) in another direction.

First hybrid spatial filter 932A can be positioned between optical element 922 and beam splitter 920 (e.g., x-polarization path). Second hybrid spatial filter 932B can be positioned between beam splitter 920 and optical element 924 (e.g., y-polarization path).

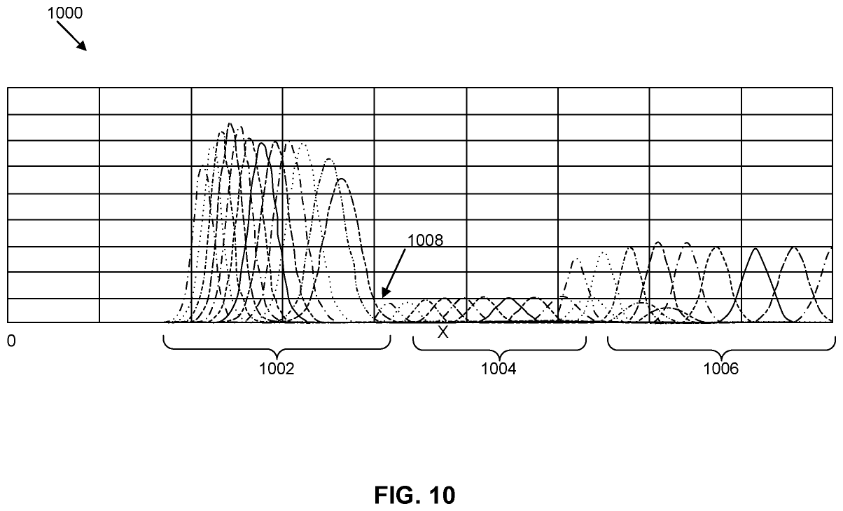

FIG. 10 shows a graph 1000 of diffraction orders in a pupil plane, according to some embodiments. In some embodiments, each diffraction order may include a plurality of wavelengths. For example, target 418 of FIGS. 4A and 4B may be illuminated using the plurality of wavelengths.

In some embodiments, first diffraction orders 1002 can include a cluster of wavelengths from 508 nm to 885 nm, for example, located at increasing pupil radial positions. The diffraction orders at the plurality of wavelength are shown with different line type. Second diffraction orders 1004 can include a cluster from 508 nm to 885 nm located at increasing pupil radial positions. Second diffraction orders 1004 (as a group) are located at a further radial position than first diffraction orders 1002 as shown in graph 1000. Third diffraction orders 1006 are located at a further radial position from second diffraction orders 1004 as shown in graph 1000.

In some embodiments, the spatial filter (e.g., hybrid spatial filter, spatial filter) may not be able to completely separate the orders because the 508 nm second order partly overlaps the 885 nm first order as shown by arrow labelled 1008. In some aspects, a first order diffraction at the longest wavelength of the plurality of wavelengths can overlap with a second order diffraction of the shortest wavelength of the plurality of wavelengths. Thus, not all of the second order light is blocked that may corrupt the intensity measurement for the shortest wavelength and compromising performance of the correction by the intensity channels.

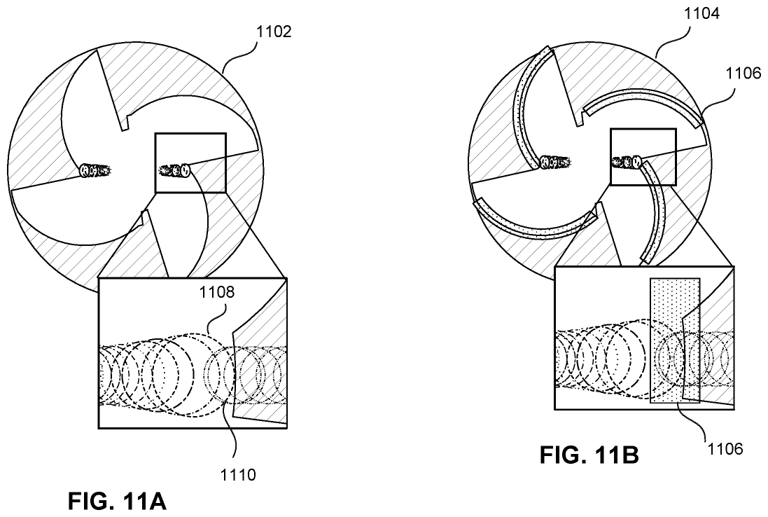

FIG. 11A is a schematic of a hybrid spatial filter 1102, according to some embodiments. First diffraction order at a first wavelength 1108 and second diffraction order at a second wavelength 1110 can overlap. As discussed previously, a spatial filter (e.g., hybrid spatial filter 800 of FIG. 8, spatial filter 600 of FIG. 6) may pass both first diffraction order at the first wavelength 1108 and second diffraction order at a second wavelength 1110 that may adversely affect the measurement in the intensity channels.

In some embodiments, a variable color filter 1106 can be used to block second order of the second wavelength as shown in FIG. 11B. In some aspects, variable color filter 1106 comprises a coated glass surface placed behind the spatial filter (e.g., hybrid spatial filter 800 of FIG. 8, spatial filter 600 of FIG. 6). In some embodiments, variable color filter and spatial filter are cemented together.

In some embodiments, a hybrid spatial filter 1104 can include a coating that can pass one or more wavelengths of the plurality of wavelengths and block one or more wavelengths of the plurality of wavelengths. For example, the coating may pass wavelengths at the high end of a band (e.g., 500 nm-900 nm) and block wavelengths at the low end of the band. In some embodiments, the coating is placed on a glass only within a narrow region around an edge of the aperture of hybrid spatial filter 1104 as shown in FIG. 11B. Thus, hybrid spatial filter 1104 can pass first diffraction order at a first wavelength 1108 (e.g., longest wavelength of the plurality of wavelengths) and can block second diffraction order at a second wavelength 1110 e.g., shortest wavelength of the plurality of wavelengths). In some aspects, an error in the measurement of Q is reduced.

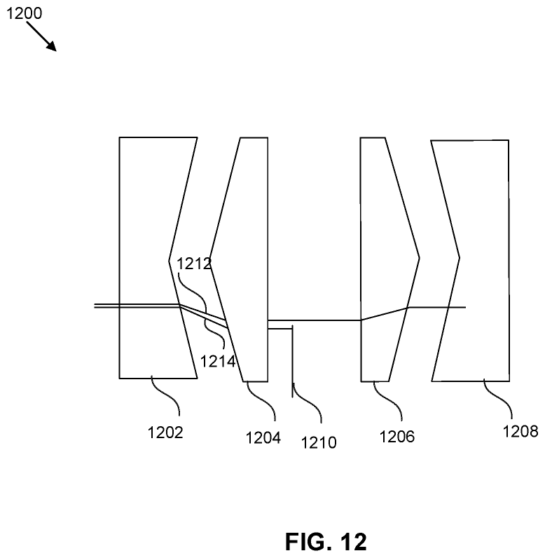

FIG. 12 show a schematic of an axicon system 1200, according to some embodiments.

Axicon system 1200 can include a first axicon that includes a first optical element 1202 and a second optical element 1204. First axicon expands the beam in the pupil. A spatial filter 1210 (e.g., a hybrid spatial filter 800 of FIG. 8B, spatial filter 600 of FIG. 6) is positioned in the expanded profile. A second axicon that includes a third optical element 1206 and a fourth optical element 1208 can restore the beam to its original diameter. In some embodiments, a first diffraction order at a first wavelength 1212 is spread away from a second diffraction order at a second wavelength 1214. Spatial filter 1210 can block second diffraction order at the second wavelength 1214. The second axicon has a reversed arrangement (mirrored) design with respect to the first axicon such as to restore the wavefront of the first diffraction order at the first wavelength 1212. In some embodiments, an apex angle of each of first optical element 1202, second optical element 1204, third optical element 1206, and fourth optical element 1208 can be equal to each other. In some aspects, the apex angle may be equal to 120°. In some aspects, first axicon and second axicon may be separated by 7 mm and at total length of the axicon optical system may be equal to 48 mm.

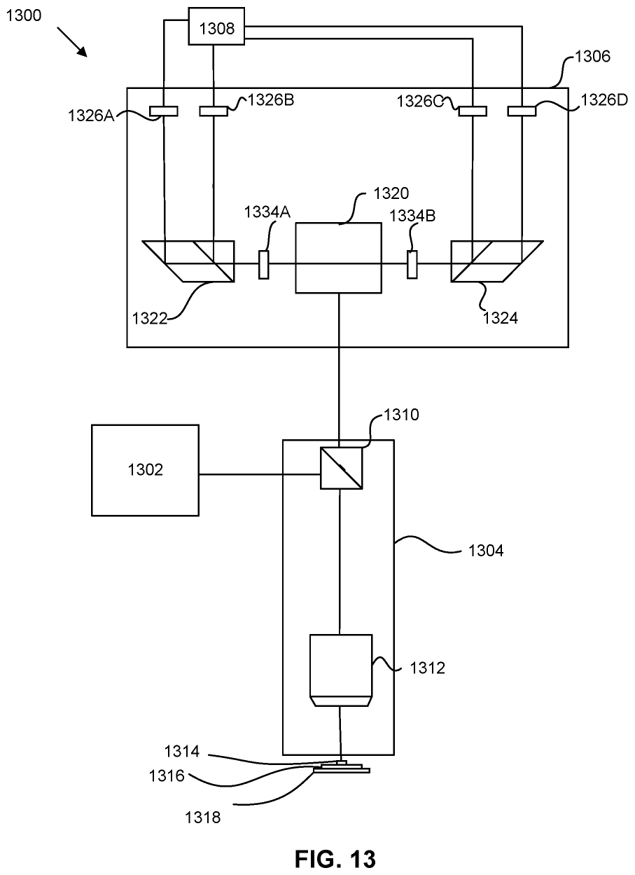

FIG. 13 shows a schematic of an optical system 1300, according to some embodiments. In some embodiments, system 1300 can also represent a more detailed view of inspection apparatus 400 (FIGS. 4A and 4B). In some embodiments, system 1300 includes an illumination system 1302, an optical system 1304, a detection system 1306, and a processor 1308. Optical system 1304 can comprise a reflective element 1310 (e.g., spot mirror) and an optical element 1312 (e.g., an objective lens). The reflective element 1310 can act as a field stop for zero order diffracted radiation. It should be appreciated the structures drawn within illumination system 1302 and optical system 1304 are not limited to their depicted positions. The positions of structures can vary as necessary, for example, as designed for a modular assembly.

FIG. 13 shows a non-limiting depiction of system 1300 inspecting a target 1314 (also “target structure”) on a substrate 1316. The substrate 1316 is disposed on a stage 1318 that is adjustable (e.g., a support structure that can move).

In some embodiments, target 1314 can comprise a diffractive structure. Target 1314 can reflect, refract, diffract, scatter, or the like, radiation. Target 1314 can be an alignment mark or target 418 of FIGS. 4A and 4B. For ease of discussion, and without limitation, radiation that interacts with a target will be termed scattered radiation throughout. The scattered radiation can be collected by optical element 1312.

Illumination system 1302 can be configured to generate a radiation beam 1336 to irradiate target 1314. Optical system 1304 can be configured collect diffraction orders diffracted from target 1314 and guide the diffraction orders to detection system 1306.

In some embodiments, detection system 1306 can include a beam splitter 1320 (one or more beam splitters) and one or more detectors. The scattered radiation can be passed by optical element 1312 and to beam splitter 1320. Beam splitter 1320 can split a portion of an optical signal into two paths. In some embodiments, each path may correspond to a polarization channel. In some aspects, a portion of the optical path is passed through beam splitter 1320 to phase channels of system 1300 (not shown).

In one aspect, an optical element 1322 (e.g., split mirror) can split the optical signal into two paths A and B. One path can contain one or more positive orders (e.g., +1, +2), and the other path can contain one or more negative orders (e.g., −1, −2). Similarly, an optical element 1324 can split the optical signal into two paths C and D. The radiation of each path A, B, C, and D can be collected by a respective lens assembly (not shown) that can focus the radiation field into each detector 1326A, 1326B, 1326C, and 1326D respectively. Detectors 1326A, 1326B, 1326C, and 1326D can be used as (or be part of) beam analyzers 430 and/or 430′ of FIGS. 4A and 4B. Each detector can provide time-varying signals (e.g., waveforms) synchronized with the physical scanning movement between system 1300 and target structure 1314. Signals from the detectors can be processed by processor 1308.

In some embodiments, detection system 1306 can further include a first axicon optical system 1334A and a second axicon optical system 1334B. First axicon optical system 1334A and second axicon optical system 1334B can be similar to axicon optical system 1200 of FIG. 12.

In some embodiments, target 1314 can be a one-dimensional target. For example, target 1314 can include a grating with segments (e.g., but not limited to grating lines) in x-direction or a grating with segments in y-direction. In some embodiments, target 1314 can include segments that are diagonal or are under any other angle. Target 1314 can include dual pitch marks. Target 1314 can include segments in, for example, x and y directions with different pitches.

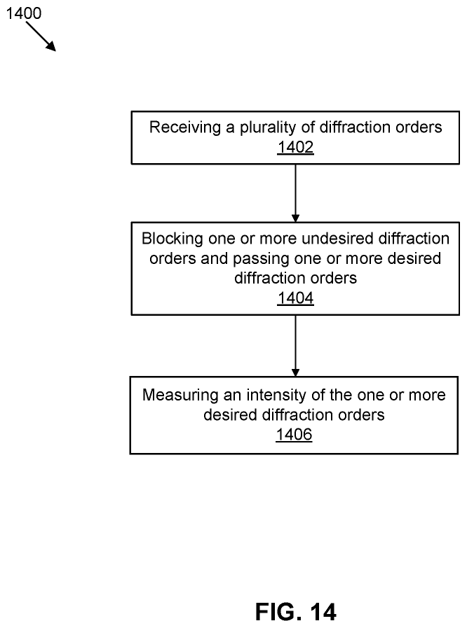

FIG. 14 shows a flowchart 1400 of method steps for performing functions as described in reference to at least FIGS. 4A, 4B, 7A, 7B, 9, and/or 13, according to some embodiments.

At step 1402, a plurality of diffraction orders may be received (e.g., using an objective of an optical system). At step 1404, one or more undesired diffraction order may be blocked and one or more desired diffraction orders may be passed using a spatial filter. In some aspects, the spatial filter may comprise one or more obscurations having an angular dependent radius that varies azimuthally. In some aspects, the spatial filter may be rotated (e.g., using a motor) based on at type of a target. The plurality of diffractions orders may be beams of a scattered radiation from a target at the plurality of wavelengths.

At step 1406, an intensity of the one or more desired diffraction orders is measured. In some embodiments, a property of the target base on a difference between measured intensities of a positive diffraction order and a negative diffraction order for at least one desired diffraction order is determined.

The method steps of FIG. 14 can be performed in any conceivable order and it is not required that all steps be performed. Moreover, the method steps of FIG. 14 described above merely reflect an example of steps and are not limiting. That is, further method steps and functions may be envisaged based upon embodiments described in reference to FIGS. 1-13.

The embodiments may further be described using the following clauses:
1. A system comprising:
an imaging system configured to receive a plurality of diffraction orders;
a spatial filter configured to block one or more undesired diffraction orders of the plurality of diffraction orders and to pass one or more desired diffraction orders of the plurality of diffraction orders, wherein the spatial filter comprises one or more obscurations having an angular dependent radius that varies azimuthally; and a detector configured to receive and measure an intensity of the one or more desired diffraction orders.
2. The system of clause 1, wherein the spatial filter comprises two or more sections, and wherein a radius of an obscuration in each section varies from a first radial distance to a second radial distance.
3. The system of clause 1, wherein the spatial filter is a motorized spatial filter and the spatial filter is configured to rotate about its center for adjustment for a varying position of the one or more desired diffraction orders.
4. The system of clause 3, wherein the spatial filter is further configured to block the one or more desired diffraction orders in a first lateral direction and to pass the one or more desired diffraction orders in a second lateral direction, wherein the first lateral direction is different than the second lateral direction.
5. The system of clause 4, wherein the spatial filter is motorized and is rotatable about a first axis, the first axis extending perpendicular to a plane defined by the first lateral direction and second lateral direction.
6. The system of clause 3, further comprising:
a blocker configured to block the one or more desired diffraction orders in a first lateral direction and to pass the one or more desired diffraction orders in a second lateral direction,
   wherein the first lateral direction is different than the second lateral direction,
   wherein the blocker is actuated by a motor, and
   wherein a movement of the blocker is rotational about its center.
7. The system of clause 1, wherein the plurality of diffraction orders are beams of a scattered radiation at a plurality of wavelengths.
8. The system of clause 7, wherein the one or more desired diffraction orders are the +1 diffraction orders.
9. The system of clause 7, further comprising:
a first axicon system configured to spatially spread a first diffraction order at a first wavelength away from a second diffraction order at a second wavelength; and
a second axicon system configured to readjust a wavefront of the first diffraction order at the first wavelength, wherein the spatial filter is positioned in an optical path between the first axicon system and the second axicon system and wherein a location of the first diffraction order at the first wavelength coincides with the location of the second diffraction order at the second wavelength.
10. The system of clause 7, further comprising
a filter configured to block one or more wavelengths of the plurality of wavelengths, and wherein the filter is positioned before the spatial filter in an optical path of the beams of the scattered radiation at the plurality of wavelengths.
11. The system of clause 7, wherein the spatial filter further comprising a coating,
wherein the coating is configured to block one or more wavelengths of the plurality of wavelengths, and
wherein the coating is deposited on an inner edge of the one or more obscurations.
12. The system of clause 1, wherein the spatial filter is a motorized spatial filter, and the system further comprises:
a radiation source configured to generate a beam of radiation;
an optical system configured to receive and direct the beam along an optical axis and toward a target so as to produce scattered radiation from the target; and
a processor configured to control a movement of the motorized spatial filter based on a type of the target.
13. The system of clause 12, wherein the processor is further configured to determine a property of the target based on a difference between measured intensities of a positive diffraction order and a negative diffraction order for at least one desired diffraction order of the one or more desired diffraction orders of the plurality of diffraction orders.
14. A spatial filter comprising:
an aperture comprising
one or more obscurations having an angular dependent radius that azimuthally varies from a first radial distance to a second radial distance; and
one or more ridges located at an inner edge of the one or more obscurations, and
wherein the aperture is configured to rotate about its center.
15. The spatial filter of clause 14, wherein the spatial filter comprises two or more sections, and wherein the angular dependent radius of an obscuration in each section varies from the first radial distance to the second radial distance.
16. The spatial filter of clause 14, wherein the aperture further comprises:
a coating configured to block one or more wavelengths, wherein the coating is deposited on the inner edge of the one or more obscurations.
17. The spatial filter of clause 14, wherein the one or more ridges are configured to block radiation in a first direction and pass radiation in a second direction, and wherein the first direction is orthogonal to the second direction.
18. A method, comprising:
receiving a plurality of diffraction orders;
blocking, using a spatial filter, one or more undesired diffraction orders of the plurality of diffraction orders and passing one or more desired diffraction orders of the plurality of diffraction orders; and
measuring an intensity of the one or more desired diffraction orders, wherein the spatial filter comprises one or more obscurations having an angular dependent radius that varies azimuthally.
19. The method of clause 18, wherein the plurality of diffraction orders are beams of a scattered radiation from a target at a plurality of wavelengths, and the method further comprising: rotating the spatial filter based on a property of the target.
20. The method of clause 19, further comprising:
determining a property of the target based on a difference between measured intensities of a positive diffraction order and a negative diffraction order for at least one desired diffraction order of the one or more desired diffraction orders of the plurality of diffraction orders.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam of radiation” or the like as used herein can encompass all types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light,” “illumination,” or the like can refer to non-matter radiation (e.g., photons, UV, X-ray, or the like). Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1. A system comprising:
an imaging system configured to receive a plurality of diffraction orders;
a spatial filter configured to block one or more undesired diffraction orders of the plurality of diffraction orders and to pass one or more desired diffraction orders of the plurality of diffraction orders, wherein the spatial filter comprises one or more obscurations having an angular dependent radius that varies azimuthally; and
a detector configured to receive and measure an intensity of the one or more desired diffraction orders.

2. The system of claim 1, wherein the spatial filter comprises two or more sections, and wherein a radius of an obscuration in each section varies from a first radial distance to a second radial distance.

3. The system of claim 1, wherein the spatial filter is a motorized spatial filter and the spatial filter is configured to rotate about its center for adjustment for a varying position of the one or more desired diffraction orders.

4. The system of claim 3, wherein the spatial filter is further configured to block the one or more desired diffraction orders in a first lateral direction and to pass the one or more desired diffraction orders in a second lateral direction, wherein the first lateral direction is different than the second lateral direction.

5. The system of claim 4, wherein the spatial filter is motorized and is rotatable about a first axis, the first axis extending perpendicular to a plane defined by the first lateral direction and second lateral direction.

6. The system of claim 3, further comprising:
a blocker configured to block the one or more desired diffraction orders in a first lateral direction and to pass the one or more desired diffraction orders in a second lateral direction,
wherein the first lateral direction is different than the second lateral direction,
wherein the blocker is actuated by a motor, and
wherein a movement of the blocker is rotational about its center.

7. The system of claim 1, wherein the plurality of diffraction orders are beams of a scattered radiation at a plurality of wavelengths.

8. The system of claim 7, wherein the one or more desired diffraction orders are the #1 diffraction orders.

9. The system of claim 7, further comprising:
a first axicon system configured to spatially spread a first diffraction order at a first wavelength away from a second diffraction order at a second wavelength; and
a second axicon system configured to readjust a wavefront of the first diffraction order at the first wavelength, wherein the spatial filter is positioned in an optical path between the first axicon system and the second axicon system and wherein a location of the first diffraction order at the first wavelength coincides with the location of the second diffraction order at the second wavelength.

10. The system of claim 7, further comprising
a filter configured to block one or more wavelengths of the plurality of wavelengths, and wherein the filter is positioned before the spatial filter in an optical path of the beams of the scattered radiation at the plurality of wavelengths.

11. The system of claim 7, wherein the spatial filter further comprising a coating,
wherein the coating is configured to block one or more wavelengths of the plurality of wavelengths, and
wherein the coating is deposited on an inner edge of the one or more obscurations.

12. The system of claim 1, wherein the spatial filter is a motorized spatial filter, and the system further comprises:
a radiation source configured to generate a beam of radiation;
an optical system configured to receive and direct the beam along an optical axis and toward a target so as to produce scattered radiation from the target; and
a processor configured to control a movement of the motorized spatial filter based on a type of the target.

13. The system of claim 12, wherein the processor is further configured to determine a property of the target based on a difference between measured intensities of a positive diffraction order and a negative diffraction order for at least one desired diffraction order of the one or more desired diffraction orders of the plurality of diffraction orders.

14. A spatial filter comprising:
an aperture comprising
one or more obscurations having an angular dependent radius that azimuthally varies from a first radial distance to a second radial distance; and
one or more ridges located at an inner edge of the one or more obscurations, and
wherein the aperture is configured to rotate about its center.

15. The spatial filter of claim 14, wherein the spatial filter comprises two or more sections, and wherein the angular dependent radius of an obscuration in each section varies from the first radial distance to the second radial distance.

16. The spatial filter of claim 14, wherein the aperture further comprises:
a coating configured to block one or more wavelengths, wherein the coating is deposited on the inner edge of the one or more obscurations.

17. The spatial filter of claim 14, wherein the one or more ridges are configured to block radiation in a first direction and pass radiation in a second direction, and wherein the first direction is orthogonal to the second direction.

18. A method, comprising:
receiving a plurality of diffraction orders;
blocking, using a spatial filter, one or more undesired diffraction orders of the plurality of diffraction orders and passing one or more desired diffraction orders of the plurality of diffraction orders; and
measuring an intensity of the one or more desired diffraction orders, wherein the spatial filter comprises one or more obscurations having an angular dependent radius that varies azimuthally.

19. The method of claim 18, wherein the plurality of diffraction orders are beams of a scattered radiation from a target at a plurality of wavelengths, and the method further comprising:
rotating the spatial filter based on a property of the target.

20. The method of claim 19, further comprising:
determining a property of the target based on a difference between measured intensities of a positive diffraction order and a negative diffraction order for at least one desired diffraction order of the one or more desired diffraction orders of the plurality of diffraction orders.
